(19) United States
(12) Patent Application Publication
(10) Pub. No.: US 2026/0013042 A1
(43) Pub. Date: Jan. 8, 2026

(54) METAL FILM AND ELECTRONIC COMPONENT

(71) Applicant: KYOCERA Corporation, Kyoto-shi, Kyoto (JP)

(72) Inventors: Hiroaki SANO, Kyoto-shi (JP); Akira IMOTO, Kyoto-shi (JP); Yuji IINO, Kyoto-shi (JP)

(73) Assignee: KYOCERA Corporation, Kyoto-shi, Kyoto (JP)

(21) Appl. No.: 18/992,857

(22) PCT Filed: Jul. 5, 2023
(86) PCT No.: PCT/JP2023/024962

§ 371 Date: Jan. 9, 2025

(30) Foreign Application Priority Data
Jul. 11, 2022 (JP) 2022-111383

(51) Int. Cl. H05K 1/09; B32B 7/04; B32B 15/20

(52) U.S. Cl. CPC H05K 1/09; B32B 7/04; B32B 15/20; B32B 2250/02; B32B 2264/101; B32B 2264/301; B32B 2307/206; B32B 2307/7376; B32B 2311/12; B32B 2311/22; B32B 2457/00

(57) ABSTRACT

A metal film includes a metal foil and a plurality of silica particles having an average particle diameter of 100 nm or less. The plurality of silica particles are in contact with a surface of the metal foil.

### CROSS-REFERENCE TO RELATED APPLICATIONS

This application is national stage application of International Application No. PCT/JP2023/024962, filed on Jul. 5, 2023, which designates the United States, incorporated herein by reference, and which claims the benefit of priority from Japanese Patent Application No. 2022-111383, filed on Jul. 11, 2022, the entire contents of which are incorporated herein by reference.

### TECHNICAL FIELD

An embodiment of the present disclosure relates to a metal film and an electronic component.

### BACKGROUND OF INVENTION

In the related art, a metal foil such as a copper foil is used for a conductor layer of a wiring board. For example, a technique of forming a wiring board by attaching a copper foil to a surface of a base material of an insulator via an adhesive in which rigid particles are mixed (for example, see Patent Document 1) has been disclosed.

### CITATION LIST

### Patent Literature

Patent Document 1: JP 59-194487 A

### SUMMARY

A metal film of the present disclosure includes a metal foil and a plurality of silica particles having an average particle diameter of 100 nm or less. The plurality of silica particles are in contact with a surface of the metal foil.

### BRIEF DESCRIPTION OF THE DRAWINGS

FIG. 1A is a cross-sectional view illustrating an example of a configuration of a metal film according to an embodiment.

FIG. 1B is an enlarged cross-sectional view illustrating a surface of the metal film according to the embodiment.

FIG. 2A is a cross-sectional view illustrating an example of a configuration of a wiring board according to an embodiment.

FIG. 2B is an enlarged cross-sectional view illustrating an interface between a metal foil and an insulating layer in the wiring board according to the embodiment.

### DESCRIPTION OF EMBODIMENTS

Embodiments of a metal film and an electronic component disclosed in the present disclosure are described below with reference to the accompanying drawings. Note that the present disclosure is not limited to the embodiments described below. The embodiments can be appropriately combined within a range so as not to contradict each other in terms of processing content. In the following embodiments, the same portions are denoted by the same reference signs, and redundant explanations are omitted.

In the related art, a metal foil such as a copper foil is used for a conductor layer of a wiring board. For example, a technique of forming a wiring board by attaching a copper foil to a surface of a base material of an insulator via an adhesive in which rigid particles are mixed has been disclosed.

However, the related art has room for further improvement in terms of improving adhesiveness between the insulating layer and the metal foil. A technique that can solve the above problem and achieve good adhesive strength to an insulating layer is expected to be implemented.

### Metal Film

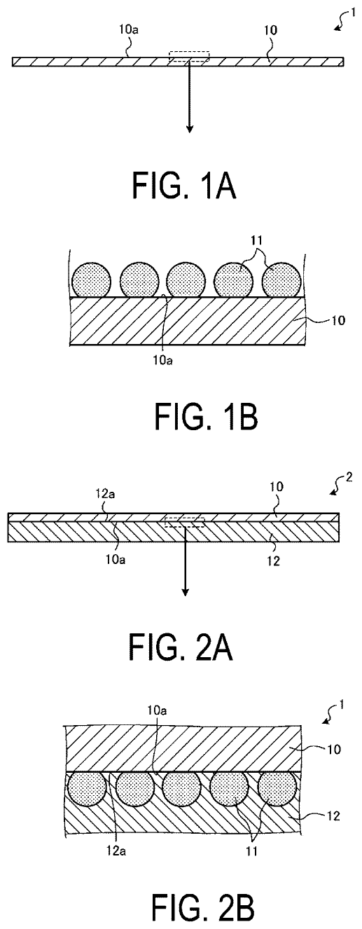

FIG. 1 is a cross-sectional view illustrating an example of a metal film 1 according to an embodiment. FIG. 1A is a cross-sectional view illustrating the entirety of the metal film 1, and FIG. 1B is an enlarged cross-sectional view of a surface of the metal film 1.

As illustrated in FIG. 1, the metal film 1 according to the embodiment includes a metal foil 10 and a plurality of silica particles 11.

The metal foil 10 is in the form of a thin film (foil) and includes metal as a main component. The metal foil 10 has a main surface 10a. The main surface 10a is an example of a surface. The metal foil 10 is not particularly limited, and examples thereof include a copper foil such as an electrolytic copper foil or a rolled copper foil, a nickel foil, and a composite foil obtained by superimposing these metal foils.

The thickness of the metal foil 10 is not particularly limited and is, for example, from about 5 μm to 105 μm. The surface roughness of the metal foil 10 is not particularly limited, and may be, for example, 0.5 μm or less or 0.3 μm or less. The surface roughness of the metal foil 10 may be 0.001 μm or more.

The silica particles 11 are spherical bodies and include silica (SiO₂) as a main component. The average particle diameter of the plurality of silica particles 11 may be 100 nm or less, or may be 20 nm or less.

As the range of the particle diameter of the plurality of silica particles 11, for example, the range of from D10 (10% integration) to D90 (90% integration) when a particle size distribution is measured may be from 5 nm to 50 nm, or may be from 10 nm to 30 nm.

In the metal film 1 according to the embodiment, as illustrated in FIG. 1B, the plurality of silica particles 11 having a nano size may be in contact with the main surface 10a of the metal foil 10. Thus, when an insulating layer 12 (see FIG. 2) is positioned to be in contact with the main surface 10a of the metal foil 10, the adhesive force between the metal foil 10 and the insulating layer 12 can be improved.

This is because the metal film 1 according to the embodiment is composed of the metal foil 10 and the plurality of silica particles 11, and thus there is almost no component that volatilizes during a firing treatment. Thus, even after the firing treatment is performed to form a wiring board 2 (see FIG. 2), the adhesive force between the metal foil 10 and the insulating layer 12 is hardly impaired.

Since the metal film 1 according to the embodiment has a configuration in which a large number of nano-sized silica particles 11 are attached to the main surface 10a of the metal foil 10, the nano-sized silica particles 11 exhibit a high adhesive force with respect to a glass ceramic being the insulating layer 12.

Accordingly, the embodiment can implement the metal film 1 having good adhesive strength to the insulating layer 12. In the metal film 1 according to the embodiment, the silica particles 11 may adhere to only a part of the surface of the metal foil 10, or the silica particles 11 may adhere to the entire surface of the metal foil 10.

In the embodiment, since the silica particles 11 included in the metal film 1 are nano-sized, even though the silica particles 11 are diffused to the insulating layer 12 side of the glass ceramic, the deterioration of the dielectric characteristics of the insulating layer 12 can be reduced. Accordingly, the embodiment can implement an electronic component having good high-frequency characteristics. The nano-sized silica particles 11 are present at an interface between the insulating layer 12 being the glass ceramic and the metal foil 10.

In the embodiment, an electrostatic attractive force may act between the metal foil 10 and the silica particles 11. Thus, strong bonding can be achieved between the metal foil 10 and the silica particles 11 without using a different material such as an adhesive. In this case, the electrostatic attractive force between the metal foil 10 and the silica particles 11 is evaluated using an electrostatic scanner. The electrostatic scanner can visualize the generation of static electricity between the metal foil 10 and the silica particles 11.

Accordingly, according to the embodiment, falling off of the silica particles 11 when the metal film 1 is handled can be reduced, so that the metal film 1 can be easily handled in the manufacturing process of an electronic component.

In the embodiment, as illustrated in FIG. 1, the silica particles 11 that are spherical may be in point contact with the metal foil 10, and a portion of the metal foil 10 not in contact with the silica particles 11 may be exposed.

The fact that the silica particles 11 that are spherical are in point contact with the metal foil 10 does not mean only the length of a contour interpreted as a point as in the case where two true spheres are in contact with each other. Actually, although the silica particles 11 are spherical, they do not have a theoretical perfect spherical shape, but have a shape close to a perfect sphere.

Therefore, a portion having a large curvature larger than that estimated from the average radius of the silica particles 11 is present in the surface of the silica particles 11, and a region where such a portion having a large curvature is in contact with the metal foil 10 has a contact area that is not a point but a surface having a predetermined area. The ratio of the area of contact between the metal foil 10 and the silica particles 11 may be from 1 to 20 or from 5 to 10 when the length of the outline of the silica particles 11 is 100.

The relative dielectric constant of the silica particles 11 is about 2.0 to 2.4. Since the metal foil 10 is in contact with the silica particles 11 having a low dielectric constant as described above, even when the insulating layer 12 being the glass ceramic has a higher relative dielectric constant than the silica particles 11, a conductive layer having a high interface electrical conductivity can be obtained by the effect of the portion in contact with the silica particles 11. The silica particles 11 are planarly dispersed at the interface between the insulating layer 12 and the metal foil 10.

In the embodiment, the silica particles 11 are planarly dispersed at the interface between the insulating layer 12 and the metal foil 10. That is, some of the silica particles 11 may have a neck portion between themselves and the metal foil 10.

This makes it possible to achieve stronger bonding between the metal foil 10 and the silica particles 11 without using a different material such as an adhesive. Accordingly, according to the embodiment, the metal film 1 can be more easily handled in the manufacturing process of an electronic component.

In the embodiment, when the unit area of the metal foil 10 is 1 in plan view, the area ratio of the plurality of silica particles 11 may be from 1% or to 60%. Thus, in an electronic component, adhesiveness between the metal foil 10 and the insulating layer 12 and electrical characteristics (for example, interface electrical conductivity or the like) can both be achieved.

For example, when the area ratio of the plurality of silica particles 11 is 1%, the plurality of silica particles 11 occupy an area of 1 μm² in the metal foil 10 having an area of 10 μm×10 μm (that is, an area of 100 μm²).

When the diameter of each of the silica particles 11 is 20 nm, the area of the silica particle 11 in plan view is 3.14×10⁻⁴ μm².

Therefore, when the area ratio of the plurality of silica particles 11 is 1%, about 3184(=1÷(3.14×10⁻⁴)) silica particles 11 are present in the metal foil 10 having an area of 10 μm×10 μm.

In this way, in the embodiment, since a large number of silica particles 11 are present on the main surface 10a of the metal foil 10, a high adhesive force can be achieved between the metal foil 10 and the insulating layer 12.

By setting the area ratio of the plurality of silica particles 11 to 60% or less, all the silica particles 11 can be disposed in a dispersed state without overlapping on the main surface 10a of the metal foil 10. The plurality of silica particles 11 are dispersed without overlapping in the thickness direction of the metal foil 10.

In the embodiment, the metal foil 10 may include copper or nickel as a main component. When the metal foil 10 includes copper as a main component, a high interface electrical conductivity and a low direct-current electric resistance value can be obtained as the conductor layer of the wiring board 2.

When the metal foil 10 includes nickel as a main component, for example, a conductor that has low resistance and that can cope with high temperature can be obtained as an electrode material of a fuel cell. When the metal foil 10 includes nickel as a main component, the metal foil 10 is also useful as an internal electrode layer of a capacitor.

In the embodiment, the silica particles 11 may be an aggregate of a plurality of primary particles having an average particle diameter from 1 nm to 5 nm. Since the silica particles 11 are formed of fine primary particles, the silica particles 11 have higher surface energy.

This makes it possible to achieve stronger bonding between the metal foil 10 and the silica particles 11 without using a different material such as an adhesive. Accordingly, according to the embodiment, the metal film 1 can be more easily handled in the manufacturing process of an electronic component.

### Wiring Board

FIG. 2 is a cross-sectional view illustrating an example of a configuration of the wiring board 2 according to the embodiment. FIG. 2A is a cross-sectional view illustrating the entirety of the wiring board 2, and FIG. 2B is an enlarged cross-sectional view illustrating the interface between the metal foil 10 and the insulating layer 12 in the wiring board 2. The wiring board 2 is an example of an electronic component.

As illustrated in FIG. 2, the wiring board 2 according to the embodiment includes the metal film 1 and the insulating layer 12. That is, the wiring board 2 according to the embodiment includes the metal foil 10, the plurality of silica particles 11, and the insulating layer 12.

The insulating layer 12 has a thin plate shape and includes an insulator as a main component. The material of the insulating layer 12 is not particularly limited, and examples thereof include various ceramic materials such as glass ceramics and zirconia-based ceramics, and organic resins.

In the wiring board 2 according to the embodiment, the metal foil 10 serves as a wiring layer. In this way, in the wiring board 2 according to the embodiment, since the wiring layer is formed of the metal foil 10 instead of a metallized layer, the wiring board 2 including a conductive layer exhibiting high conductivity can be obtained. In this case, the metal foil 10 may include copper as a main component.

In the wiring board 2 according to the embodiment, the metal foil 10 and the insulating layer 12 are bonded to each other so that the main surface 10a of the metal foil 10 is in contact with a main surface 12a of the insulating layer 12. That is, in the embodiment, the metal foil 10 is bonded to the insulating layer 12 via the plurality of silica particles 11. Therefore, in the embodiment, as described above, the adhesive force between the metal foil 10 and the insulating layer 12 can be improved.

In the embodiment, since the silica particles 11 included in the metal film 1 are nano-sized, even though the silica particles 11 are diffused to the insulating layer 12 side of the glass ceramic, the deterioration of the dielectric characteristics of the insulating layer 12 can be reduced. Accordingly, the embodiment can implement the wiring board 2 having good high-frequency characteristics.

### Electronic Component

The present disclosure is also applicable to the following electronic component. This electronic component also includes a metal foil 10 (see FIG. 2), a plurality of silica particles 11 (see FIG. 2), and an insulating layer 12 (see FIG. 2).

As in the above wiring board 2, the electronic component may have a configuration in which the metal foil 10 is disposed on a main surface 12a of the insulating layer 12. Alternatively, the electronic component may also have a configuration in which the metal foil 10 is disposed on both surfaces of the insulating layer 12.

In this case, the material of the metal foil 10 is preferably nickel. When the material of the metal foil 10 is nickel, a ceramic material exhibiting dielectric properties is suitable as the material of the insulating layer. The ceramic material exhibiting dielectric properties may be referred to as a dielectric ceramic.

Examples of the dielectric ceramic include a ceramic material including barium titanate as a main component. The term “main component” means that barium titanate is contained in the dielectric ceramic in an amount of 80 (mole %) or more. The dielectric ceramic is applied to, for example, a dielectric layer of a multilayer ceramic capacitor.

### Fuel Cell

The present disclosure is also applicable to the following fuel cell. This fuel cell also includes a metal foil 10 (see FIG. 2), a plurality of silica particles 11 (see FIG. 2), and an insulating layer 12 (see FIG. 2).

The fuel cell includes a fuel electrode and a support. The fuel electrode includes a solid electrolyte material and nickel. In the fuel cell, the main component of the material of the fuel electrode is zirconia. In this case, the material of the metal foil 10 is preferably nickel. Also in this case, the nickel conductor preferably has the plurality of silica particles 11 located on the surface thereof.

### EXAMPLES

Examples of the present disclosure will be specifically described below. Note that in the examples to be described below, a metal film having a copper foil is first described and then a wiring board including such a metal film and an insulating layer made of a glass ceramic is described; however, the present disclosure is not limited to the following examples.

### Sample 1

First, a copper foil having a thickness of 18 μm was prepared as a material of a metal foil. A plurality of silica particles having an average particle diameter of 20 nm were prepared. The silica particles were an aggregate of primary particles having a particle diameter of approximately 1 nm to 10 nm.

Subsequently, the prepared copper foil was subjected to a treatment of removing an oxide film on the surface with hydrochloric acid, followed by alkaline washing and water washing.

Subsequently, the water-washed copper foil was subjected to a treatment of adhering the plurality of silica particles. Specifically, first, silica particles were prepared in an amount of about 50% by area with respect to a main surface of the copper foil.

Subsequently, the copper foil was attached to a metal substrate, a metal frame was disposed around the copper foil, the silica particles in the amount described above were put into the frame, and ultrasonic waves were applied to the metal substrate to disperse the silica particles on the copper foil.

After the dispersion treatment, a metal plate made of stainless steel was placed on the silica particles, and the silica particles were pressurized at a predetermined pressure via the metal plate. Thus, a metal film of sample 1 in which a plurality of silica particles were attached to the main surface was obtained. The ratio of the attached silica particles to the silica particles put into the frame was about 10% to 20%.

Subsequently, a wiring board of sample 1 was produced using the metal film obtained as described above. First, a glass-ceramic green sheet having a thickness of 0.2 mm was prepared, and six green sheets were layered.

Subsequently, metal films were attached to both main surfaces of the green sheet. At this time, the green sheet and the metal film were disposed so that the silica particles of the metal film adhere to the green sheet.

Subsequently, the obtained layered body of the green sheet and the metal film was fired. The firing was performed in a reducing atmosphere using a hydrogen-nitrogen mixed gas at a maximum temperature of 930° C. for a holding time of 2 hours.

Subsequently, the copper foil was subjected to an etching treatment so that the copper foil of the obtained fired body had a predetermined shape. Such an etching treatment was carried out in a conventional manner. This resulted in obtaining the wiring board of sample 1.

### Sample 2

A metal film and a wiring board of sample 2 were obtained by the same method and under the same conditions as those of sample 1 except that a borosilicate glass powder having an average particle diameter of 1 μm was used instead of the nano-sized silica particles in the step of preparing the metal film.

### Sample 3

A metal film and a wiring board of sample 3 were obtained by the same method and under the same conditions as those of sample 1 except that the nano-sized silica particles were attached to the copper foil with an adhesive made of an organic resin in the step of preparing the metal film.

### Various Evaluations

Subsequently, the metal films and the wiring boards of samples 1 to 3 obtained as described above were visually observed. As a result, in the metal film of sample 1, the silica particles were firmly fixed to the copper foil, and did not fall off from the copper foil even when the metal film was handled. In the metal film of sample 1, the silica particles were bonded to the copper foil by electrostatic force and van der Waals force.

Subsequently, the metal films and the wiring boards of samples 1 to 3 obtained as described above were cut, the cut surfaces were filled with resin and were mirror polished, and then the cross sections were observed with a scanning electron microscope (SEM). As a result, in the metal film of sample 1, a plurality of silica particles strongly bonded to the copper foil by neck bonding were observed.

In the wiring board of sample 1, the silica particles were present in a particulate form between the copper foil and the glass ceramic, and were bonded to the glass ceramic. In the wiring board of sample 1, the periphery of the neck bonding portion of the silica particles was filled with the glass ceramic.

In this way, in the wiring board of sample 1, since the nano-sized silica particles were used as a binder in the copper foil, solid solution in the glass ceramic was suppressed, and the silica particles were firmly bonded to the copper foil in the particulate state.

On the other hand, in the wiring board of sample 2, the glass powder was in solid solution on the insulating layer side, and was hardly present in the particulate state between the copper foil and the glass ceramic.

The presence or absence of conductor peeling in each of the wiring boards of samples 1 to 3 obtained as described above was evaluated. As a sample for evaluation, a sample in which a copper foil was layered on both surfaces of an insulating layer with 10 mm to 50 mm per side was used.

In the evaluation of the conductor peeling, the sample for evaluation was first cut at a position of about ½ of the length in one direction, and each interface between the insulating layer and the copper foil in the cross section was observed. When at least one peeled portion was observed, “presence of peeling” was determined, and when no peeled portion was observed at all the interfaces, “absence of peeling” was determined.

Note that in the above determination, the state of “presence of peeling” was determined when a length of a region where the insulating layer and the copper foil were separated from each other by 0.1 mm or more was 1 mm or more. As a result, the wiring board of sample 1 was determined as “absence of peeling”, whereas the wiring boards of samples 2 and 3 were determined as “presence of peeling”.

The interface electrical conductivity of each of the wiring boards of samples 1 to 3 obtained as described above was measured. The interface electrical conductivity was measured by a cylindrical dielectric resonator method to be described below. As a sample for measurement, a sample having a diameter of 50 mm and including the copper foil formed substantially entirely on both surfaces thereof was used.

The method of measuring interface electrical conductivity by using the cylindrical dielectric resonator method is a method of measuring electrical conductivity at an interface between a copper foil and an insulating layer, that is, at a conductor interface, by attaching the insulating layer including the conductor formed therein to both end surfaces or one end surface of a dielectric cylinder made of a dielectric material having a known relative permittivity and dielectric loss such that a predetermined relationship is established and thereby forming a dielectric resonator.

The principle of this measurement method is based on the fact that when conductor plates large enough to ignore an edge effect (usually, conductor plates having a diameter D of about three times a diameter d of the dielectric cylinder) are placed in parallel on both end surfaces of the dielectric cylinder having a predetermined dimensional ratio (height h/diameter d) and supported thereon to form an electromagnetic field resonator, a high-frequency current flowing through the conductor plates in a TEomn resonance mode (hereinafter, referred to as the TEomn mode) is distributed only on a short-circuited surface, that is, a facing surface between the dielectric body and the conductor.

In the dielectric resonator, by using the fact that the high-frequency current flowing through the conductor due to the TEomn mode (m=1, 2, 3, . . . , n=1, 2, 3, . . . ) is distributed only at an interface between the conductor and a dielectric board in contact with the dielectric cylinder, the interface electrical conductivity can be calculated from the measured resonant frequency f0 of the TEomn mode (m=1, 2, 3, . . . , n=1, 2, 3, . . . ) and no-loads Q and Qu. The interface electrical conductivity was measured in a frequency range of from 1 GHz to 49 GHz, and was evaluated as a relative value when the interface electrical conductivity at a direct current was set to 100%.

As a result, in the wiring board of sample 1, the interface electrical conductivity was 80% or more in the frequency range of from 1 GHz to 49 GHz. On the other hand, in the wiring boards of sample 2 and Sample 3, the interface electrical conductivity was 80% in the frequency range of from 1 GHz to 49 GHz.

A thermal shock resistance test was performed by immersing the wiring boards of samples 1 to 3 obtained as described above in a heated solder bath for about 1 second. In this thermal shock resistance test, the temperature of the solder bath was set to two temperatures of 325° C. (that is, ΔT=300° C.) and 355° C. (that is, ΔT=330° C.).

Cracks generated in the wiring board were confirmed by a method of observing a cross-sectionally polished sample of the wiring board under a stereoscopic microscope. As a result, the wiring board of sample 1 exhibited good thermal shock resistance at any temperature, whereas the wiring boards of sample 2 and sample 3 did not exhibit good thermal shock resistance at any temperature.

Although an embodiment of the present disclosure has been described above, the present disclosure is not limited to the embodiment described above, and various changes can be made without departing from the spirit of the present disclosure. For example, although an example in which a fine powder of silica particles is attached to the metal foil 10 has been illustrated in the embodiment described above, the present disclosure is not limited to such an example.

For example, a ceramic fine powder (for example, alumina fine powder or the like) other than silica may be attached to the metal foil 10. In this case as well, the same and/or similar effects as those in the embodiment described above can be obtained.

Additional effects and other aspects can be easily derived by a person skilled in the art. Thus, a wide variety of aspects of the present disclosure are not limited to the specific details and representative embodiments represented and described above. Accordingly, various changes are possible without departing from the spirit or scope of the general inventive concepts defined by the appended claims and their equivalents.

Note that the present technique can also have the following configurations.

### (1)

A metal film including:
a metal foil; and
a plurality of silica particles having an average particle diameter of 100 nm or less, the plurality of silica particles being in contact with a surface of the metal foil.

### (2)

The metal film according to (1), wherein an electrostatic attractive force acts between the metal foil and the plurality of silica particles.

### (3)

The metal film according to (1) or (2), wherein each of the plurality of silica particles is a spherical body and is in point contact with the metal foil, and a portion of the metal foil not in contact with the plurality of silica particles is exposed.

### (4)

The metal film according to any one of (1) to (3), wherein when a unit area of the metal foil is 1 in plan view, an area ratio of the plurality of silica particles is from 1% or to 60%.

### (5)

The metal film according to any one of (1) to (4), wherein the metal foil includes copper or nickel as a main component.

### (6)

The metal film according to any one of (1) to (5), wherein the plurality of silica particles is an aggregate of a plurality of primary particles having an average particle diameter of from 1 nm to 5 nm.

### (7)

An electronic component including:
the metal film according to any one of (1) to (6); and
an insulating layer,
wherein the metal foil is bonded to the insulating layer via the plurality of silica particles.

### (8)

The electronic component according to (7), wherein the metal foil is composed of at least one kind of metal foil selected from the group consisting of a copper foil such as an electrolytic copper foil or a rolled copper foil, a nickel foil, and a composite foil obtained by superimposing these metal foils.

### (9)

The electronic component according to (7) or (8), wherein a surface roughness of the metal foil is from 0.001 μm to 0.5 μm.

### (10)

The electronic component according to any one of (7) to (9), wherein a range of a particle diameter of the plurality of silica particles is from 5 nm to 50 nm in a range of from D10 (10% integration) to D90 (90% integration) when a particle size distribution is measured.

### (11)

The electronic component according to any one of (7) to (10), wherein the plurality of silica particles is present at an interface between the metal foil and the insulating layer.

### (12)

The electronic component according to any one of (7) to (11), wherein a portion having a large curvature larger than a curvature estimated from an average radius of the plurality of silica particles is present in a surface of the plurality of silica particles, and a region where the portion having a large curvature is in contact with the metal foil is a surface having a predetermined area.

### (13)

The electronic component according to any one of (7) to (12), wherein the plurality of silica particles is planarly dispersed at an interface between the insulating layer and the metal foil.

### (14)

The electronic component according to any one of (7) to (13), wherein the plurality of silica particles is dispersed without overlapping on a main surface of the metal foil.

### (15)

The electronic component according to any one of (7) to (14), wherein some of the plurality of silica particles include a neck portion between themselves and the metal foil.

1. A metal film comprising:
a metal foil; and a plurality of silica particles having an average particle diameter of 100 nm or less,
the plurality of silica particles being in contact with a surface of the metal foil.

2. The metal film according to claim 1, wherein
an electrostatic attractive force acts between the metal foil and the plurality of silica particles.

3. The metal film according to claim 1, wherein
each of the plurality of silica particles is a spherical body and is in point contact with the metal foil, and
a portion of the metal foil not in contact with the plurality of silica particles is exposed.

4. The metal film according to claim 1, wherein
when a unit area of the metal foil is 1 in plan view, an area ratio of the plurality of silica particles is from 1% or to 60%.

5. The metal film according to claim 1, wherein
the metal foil comprises copper or nickel as a main component.

6. The metal film according to claim 1, wherein
the plurality of silica particles is an aggregate of a plurality of primary particles having an average particle diameter of from 1 nm to 5 nm.

7. An electronic component comprising:
the metal film according to claim 1; and
an insulating layer,
wherein the metal foil is bonded to the insulating layer via the plurality of silica particles.

8. The electronic component according to claim 7, wherein
the metal foil is composed of at least one kind of metal foil selected from the group consisting of a copper foil such as an electrolytic copper foil or a rolled copper foil, a nickel foil, and a composite foil obtained by superimposing these metal foils.

9. The electronic component according to claim 7, wherein
a surface roughness of the metal foil is from 0.001 μm to 0.5 μm.

10. The electronic component according to claim 7, wherein
a range of a particle diameter of the plurality of silica particles is from 5 nm to 50 nm in a range of from D10 (10% integration) to D90 (90% integration) when a particle size distribution is measured.

11. The electronic component according to claim 7, wherein
the plurality of silica particles is present at an interface between the metal foil and the insulating layer.

12. The electronic component according to claim 7, wherein
a portion having a large curvature larger than a curvature estimated from an average radius of the plurality of silica particles is present in a surface of the plurality of silica particles, and a region where the portion having a large curvature is in contact with the metal foil is a surface having a predetermined area.

13. The electronic component according to claim 7, wherein
the plurality of silica particles is planarly dispersed at an interface between the insulating layer and the metal foil.

14. The electronic component according to claim 7, wherein
the plurality of silica particles is dispersed without overlapping on a main surface of the metal foil.

15. The electronic component according to claim 7, wherein
some of the plurality of silica particles comprise a neck portion between themselves and the metal foil.
